(19) United States
(12) Patent Application Publication
(10) Pub. No.: US 2020/0331796 A1
(43) Pub. Date: Oct. 22, 2020

(54) CONDUCTIVE PASTE FOR SOLAR CELL ELECTRODE, GLASS FRIT CONTAINED THEREIN, AND SOLAR CELL

(71) Applicant: LS-NIKKO COPPER INC., Ulsan (KR)

(72) Inventors: Chung Ho KIM, Namyangju (KR); Mun Seok JANG, Seoul (KR); Hwa Young NOH, Hwaseong (KR); In Chul KIM, Yongin (KR); Min Soo KO, Seoul (KR); Tae Hyun JUN, Seongnam (KR); Kang Ju PARK, Seongnam (KR)

(21) Appl. No.: 16/760,323

(22) PCT Filed: Oct. 17, 2018
(86) PCT No.: PCT/KR2018/012281

§ 371 Date: Apr. 29, 2020

(30) Foreign Application Priority Data
Oct. 31, 2017 (KR) 10-2017-0143378

(51) Int. Cl. C03C 8/12; C03C 4/14; C03C 8/10; C03C 8/18; H01L 31/0224

(52) U.S. Cl. CPC C03C 8/12; C03C 4/14; C03C 8/10; C03C 2205/00; H01L 31/022425; C03C 2204/00; C03C 8/18

(57) ABSTRACT

A glass frit, according to an embodiment of the present invention, is a glass frit contained in a conductive paste for a solar cell electrode, which comprises an alkali metal oxide, wherein the total molar ratio of the alkali metal oxide to the total glass frit is 0.1 to 0.2.

### TECHNICAL FIELD

The present invention relates generally to a conductive paste for a solar cell electrode, a glass frit contained therein, and a solar cell. More particularly, the present invention relates to a conductive paste for a solar cell electrode having an improved composition, a glass frit contained therein, and a solar cell.

### BACKGROUND ART

Recently, as an exhaustion of existing energy resources such as oil and coal has been expected, interest in alternative energy sources to replace the same has been increasing. Of these, a solar cell has been spotlighted as a next-generation cell that converts solar energy into electrical energy.

Such a solar cell may be manufactured by forming various layers and electrodes according to design. Meanwhile, solar cell efficiency may be determined according to the design of these various layers and electrodes. In order to commercialize a solar cell, it is necessary to overcome low efficiency and low productivity, and thus a solar cell having a structure capable of maximizing the efficiency and productivity of the solar cell is required.

As an example for this, as in Patent Document 1 (Korean Patent No. 10-1575966), an insulating film includes an aluminum oxide film in order to improve passivation characteristics has been disclosed. Here, when forming a conductive paste on the insulating film and performing firing during manufacturing of a solar cell, the conductive paste has to pass through the insulating film and be connected to a conductivity type region. In the solar cell of this structure, a conventional conductive paste may not sufficiently etch an aluminum insulating film, and thus an electrode may not be stably connected to the conductivity type region. This may cause a problem that the solar cell may not operate or that the efficiency of the solar cell may be significantly reduced.

### DISCLOSURE

### Technical Problem

Accordingly, the present invention has been made keeping in mind the above problems occurring in the related art, and an objective of the present invention is to provide a conductive paste for a solar cell electrode, the conductive paste being capable of improving the efficiency and characteristics of a solar cell, and provide a glass frit contained therein.

However, the objectives of the present invention are not limited to the above-mentioned objective, and other objectives not mentioned will be clearly understood by those skilled in the art from the following description.

### Technical Solution

A glass frit according to an embodiment of the present invention is a glass frit contained in a conductive paste for a solar cell electrode, and includes an alkali metal oxide, wherein a total molar ratio of the alkali metal oxide to the entire glass frit is 0.1 to 0.2.

The alkali metal oxide may include at least one of lithium oxide (Li₂O), sodium oxide (Na₂O), and potassium oxide (K₂O).

The alkali metal oxide may be used by mixing at least two or more of the lithium oxide, the sodium oxide, and the potassium oxide.

When the glass frit includes the lithium oxide, a molar ratio of the lithium oxide to the entire glass frit may be 0.01 to 0.13; when the glass frit includes the sodium oxide, a molar ratio of the sodium oxide to the entire glass frit may be 0.01 to 0.1; and when the glass frit includes the potassium oxide, a molar ratio of the potassium oxide to the entire glass frit may be 0.01 to 0.1.

The alkali metal oxide may individually include the lithium oxide, the sodium oxide, and the potassium oxide, and the lithium oxide or the sodium oxide may be included in a higher molar ratio than the potassium oxide.

The lithium oxide may be included in a higher molar ratio than each of the sodium oxide and the potassium oxide.

The glass frit may include lead oxide, tellurium oxide, bismuth oxide, and silicon oxide, and may further include at least one of boron oxide, zinc oxide, aluminum oxide, titanium oxide, calcium oxide, magnesium oxide, and zirconium oxide.

The glass frit may include the alkali metal oxide in a higher molar ratio than an alkaline earth metal oxide.

The glass frit may not include an alkaline earth metal oxide.

A conductive paste for a solar cell electrode according to an embodiment of the present invention is a conductive paste for a solar cell electrode, the conductive paste including: a metal powder; a glass frit; an organic binder; and a glass frit, wherein the above-mentioned glass frit may be included.

A solar cell according to an embodiment of the present invention includes: a semiconductor substrate; a first conductivity type region formed on a front surface of the semiconductor substrate; a passivation film formed on the first conductivity type region and including an aluminum oxide film; a front electrode penetrating the passivation film to be connected to the first conductivity type region; and a back electrode formed on a back surface of the semiconductor substrate. The front electrode may be produced by applying the conductive paste of claim 10, followed by firing.

The front electrode may have a contact resistance of equal to or less than 40 ohm·cm².

### Advantageous Effects

According to the present invention, a glass frit includes an alkali metal oxide in a specific molar ratio, and thus it is possible to effectively etch an aluminum oxide film and to improve contact characteristics. Accordingly, it is possible to improve the fill factor and efficiency of the solar cell. Further, it is possible to effectively improve the contact characteristics by adjusting the amount of the composition (particularly the alkali metal oxide) in the glass frit in accordance with the thickness of the aluminum oxide film.

### DESCRIPTION OF DRAWINGS

FIG. 1 is a sectional view schematically illustrating an example of a solar cell to which a conductive paste for a solar cell electrode according to the present invention is applied.

### MODE FOR INVENTION

Prior to describing the present invention in detail below, it should be understood that the terms used herein are merely intended to describe specific embodiments and are not to be construed as limiting the scope of the present invention, which is defined by the appended claims. Unless otherwise defined, all terms including technical and scientific terms used herein have the same meaning as commonly understood by one of ordinary skill in the art to which this invention belongs.

Throughout this specification and the claims, unless otherwise defined, the terms “comprise”, “comprises”, and “comprising” will be understood to imply the inclusion of a stated object, a step or groups of objects, and steps, but not the exclusion of any other objects, steps or groups of objects or steps.

Meanwhile, unless otherwise noted, various embodiments of the present invention may be combined with any other embodiments. In particular, any feature which is mentioned preferably or favorably may be combined with any other features which may be mentioned preferably or favorably. Hereinafter, a description will be given of embodiments of the present invention and effects thereof with reference to the accompanying drawings.

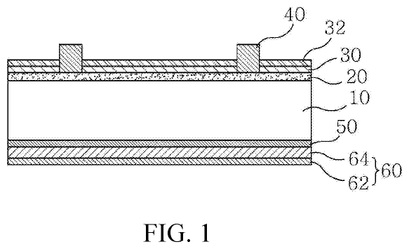

First, an example of a solar cell to which a conductive paste for a solar cell electrode according to the present invention is applied will be described with reference to FIG. 1, and then the conductive paste for the solar cell electrode according to the present invention and a glass frit contained therein will be described in detail.

FIG. 1 is a sectional view schematically illustrating the example of the solar cell to which the conductive paste for the solar cell electrode according to the present invention is applied.

Referring to FIG. 1, the solar cell according to the example of the present invention includes a semiconductor substrate 10, a first conductivity type region 20 formed on a front surface of the semiconductor substrate 10, an anti-reflection film 30 and a passivation film 32 formed on the first conductivity type region 20, and a front electrode 40 penetrating the anti-reflection film 30 and the passivation film 32 and electrically connected to the first conductivity type region 20. Additionally, a second conductivity type region 50 formed on a back surface of the semiconductor substrate 10, and a back electrode 60 electrically connected to the second conductivity type region 50 may be included.

The semiconductor substrate 10 may be a silicon substrate (e.g., a silicon wafer), may have a second conductivity type (e.g., p-type), and may have a thickness of 180 to 250μm.

The first conductivity type region 20 may be a region having a first conductivity type (e.g., n-type) formed by doping a first conductivity type dopant on a portion of the front surface of the semiconductor substrate 10, and may have a thickness of 0.3 to 0.6μm.

The anti-reflection film 30 located on the first conductivity type region 20 may serve to prevent light incident on the front surface of the semiconductor substrate from being reflected. Various known materials may be used as the anti-reflection film 30, for example, a silicon nitride film or the like.

The passivation film 32 located on the anti-reflection film 30 may be composed of an aluminum oxide film, and may have a thickness of 2 to 20 nm. The passivation layer 32 may improve passivation characteristics by fixed charge and hydrogen passivation to improve open-circuit voltage (Voc) and short-circuit current (Isc).

Although the passivation film 32 composed of an aluminum oxide film is illustrated as being located on the anti-reflection film 30, the present invention is not limited thereto. For example, the passivation film 32 composed of an aluminum oxide film may be formed on the first conductivity type region 20 and the anti-reflection film 30 may be formed thereon.

The front electrode 40 may be formed by applying a conductive paste mixed with a metal powder, a glass frit, and an organic vehicle including a solvent and a binder on the anti-reflection film 30 and the passivation film 32, followed by firing. Due to the fact that the conductive paste has to be connected to the first conductive type region 20 by etching and penetrating the anti-reflection film 30 and the passivation film 32 during firing, in the present invention, a conductive paste capable of effectively etching the passivation film 32 composed of an aluminum oxide film is used. The conductive paste may include a glass frit of a specific composition, which will be described in more detail later.

The second conductivity type region 50 may be a back surface field (BSF) region having a second conductivity type (e.g., p-type) formed by doping a second conductivity type dopant on a portion of the back surface of the semiconductor substrate 10. The formation of the BSF region can prevent recombination of electrons and improve collection efficiency of generated carriers. The second conductivity type region 50 may be formed by various processes, for example, by a process in which substances of the back electrode 60 are diffused when at least a portion of the back electrode 60 (i.e., a first electrode portion 62) is formed.

The back electrode 60 may include aluminum and may include the first electrode portion 62 located adjacent to the second conductivity type region 50. For example, the first electrode portion 62 may be formed by applying an aluminum paste composition consisting of an aluminum powder, a glass frit, an organic vehicle, and additives by screen printing or the like, followed by drying and firing at a temperature of equal to or greater than 660° C. (melting point of aluminum). When firing the aluminum paste composition, aluminum may diffuse into the semiconductor substrate to form the second conductivity type region 50. The back electrode 60 may further include a second electrode portion 64 formed on the first electrode portion 62 and including silver (Ag). The back electrode 60 may be foamed entirely on the back side of the semiconductor substrate 10, but the present invention is not limited thereto.

Hereinafter, the conductive paste for the solar cell electrode according to the embodiment of the present invention is a conductive paste that can be applied when forming an electrode of a solar cell, and a conductive paste for a solar cell electrode that can effectively etch an aluminum oxide film is provided. For example, the conductive paste for the solar cell electrode according to the embodiment of the present invention may be applied to form the front electrode 40, but the present invention is not limited thereto. For example, the conductive paste may be applied to form at least a portion of the back electrode 60.

The conductive paste for the solar cell electrode according to the present invention may include a metal powder, a glass frit, a binder, and a solvent, which will be described in detail.

As the metal powder, silver (Ag) powder, gold (Au) powder, platinum (Pt) powder, nickel (Ni) powder, copper (Cu) powder, or the like may be used. As the metal powder, one of the above-mentioned powders may be used solely, an alloy of the above-mentioned metals may be used, or a mixed powder of at least two of the above-mentioned powders may be used. Additionally, a metal powder obtained by performing a hydrophilic treatment or the like on the surface of the above metal powder may be used.

Of these, it is preferable to use silver (Ag) powder which is mainly used for the front electrode 40 due to its excellent electrical conductivity. The silver powder is preferably a pure silver powder. Alternatively, a silver-coated composite powder in which a silver layer is formed on at least the surface thereof, or an alloy including silver as a main component may be used. Further, other metal powders may be used in mixture. Examples may include aluminum, gold, palladium, copper, and nickel.

The silver powder may have an average particle diameter of 0.1 to 10μm, and preferably 0.5 to 5μm when considering ease of pasting and density during firing, and the shape thereof may be at least one of spherical, needle-like, plate-like, and amorphous. The silver powder may be used by mixing two or more powders having different average particle diameters, particle size distributions, and shapes.

The glass frit according to the present invention includes an alkali metal oxide, and the total molar ratio of the alkali metal oxide to the entire glass frit may be 0.1 to 0.2. The glass frit including the alkali metal oxide may improve characteristics of etching an aluminum oxide film. When the above-described molar ratio is less than 0.1, the characteristics of etching the aluminum oxide film may not be sufficient. When the above-described molar ratio is greater than 0.2, the aluminum oxide film can be effectively etched, while contact characteristics with the first conductive type region 20 may not be excellent.

In an example, the alkali metal oxide may include at least one of lithium oxide (e.g., Li₂O), sodium oxide (e.g., Na₂O), and potassium oxide (e.g., K₂O). In particular, when at least two or more of lithium oxide, sodium oxide, and potassium oxide are used in mixture, the etching characteristics of the aluminum oxide film may be further improved.

When the glass frit includes lithium oxide, the molar ratio of lithium oxide to the entire glass frit may be 0.01 to 0.13. When the glass frit includes sodium oxide, the molar ratio of sodium oxide to the entire glass frit may be 0.01 to 0.1. When the glass frit includes potassium oxide, the molar ratio of potassium oxide to the entire glass frit may be 0.01 to 0.1. Within this range, the etching characteristics of the aluminum oxide film and the contact characteristics with the first conductivity type region can be effectively improved.

Here, when the glass frit includes all of lithium oxide, sodium oxide, and potassium oxide, and lithium oxide or sodium oxide is included in a higher molar ratio than potassium oxide (particularly, lithium oxide is included in a higher molar ratio than each of sodium oxide and potassium oxide), contact resistance with the first conductivity type region 20 may be further reduced.

The glass frit may include as main substances (substances having a molar ratio of equal to or greater than 0.5 to the entire glass frit) lead oxide (e.g., PbO), tellurium oxide (e.g., TeO₂), bismuth oxide (e.g., Bi₂O₃), and silicon oxide (e.g., SiO₂). The glass frit may further include at least one of boron oxide, zinc oxide, aluminum oxide, titanium oxide, calcium oxide, magnesium oxide, and zirconium oxide as an additional substance. For example, the molar ratio of lead oxide to the entire glass frit may be 0.1 to 0.29, the molar ratio of tellurium oxide to the entire glass frit may be 0.2 to 0.38, the molar ratio of bismuth oxide to the entire glass frit may be 0.03 to 0.2, and the molar ratio of silicon oxide to the entire glass frit may be equal to or less than 0.2. Further, the molar ratio of each additional substance to the entire glass frit may be equal to or less than 0.2 (e.g., equal to or less than 0.06).

By organically combining the amount of each component, it is possible to prevent an increase in the line width of the front electrode, ensuring excellent contact resistance, and ensuring excellent short-circuit current characteristics. In particular, when the amount of lead oxide is too high, there may be a problem in that it may be difficult to ensure eco-friendliness, and in that the viscosity may become too low during melting and thus the line width of the front electrode may increase during firing. Therefore, it is preferable that lead oxide is included within the above range in the glass frit. Further, for example, when the alkali metal oxide is included in the glass frit in the above-described range, when a large amount of alkaline earth metal oxide (i.e., calcium oxide, magnesium oxide, or the like) is included, contact resistance may increase. Accordingly, the glass frit may include the alkali metal oxide at a higher molar ratio than the alkaline earth metal oxide, and for example, the glass frit may not include the alkaline earth metal oxide.

In the above-described description, it is illustrated that the glass frit is a leaded glass frit so that the anti-reflection film 30 and the passivation film 32 can be etched stably during firing of the conductive paste. However, the present invention is not limited to this, and the glass frit may be a lead-free glass frit that does not include lead oxide.

The average particle diameter of the glass frit is not limited, but may fall within the range of 0.5 to 10μm, and the glass frit may be used by mixing different types of particles having different average particle diameters. Preferably, at least one glass frit has an average particle diameter D50 of equal to or greater than 3μm and equal to or less than 5μm. This makes it possible to ensure excellent reactivity during firing, and in particular, minimize damage to an n-layer at a high temperature, improve adhesion, and ensure excellent open-circuit voltage (Voc). It is also possible to reduce an increase in the line width of an electrode during firing.

Further, the glass transition temperature (Tg) of the glass frit is not limited, but may be 200 to 600° C. Preferably, the glass transition temperature falls within the range of equal to or greater than 200° C. and less than 300° C. By using a glass frit having a low glass transition temperature of less than 300° C., melting uniformity can be increased, and the characteristics of the solar cell can be made uniform. Additionally, excellent contact characteristics can be ensured even during low temperature/quick firing, and optimization for high surface resistance (90 to 120 Ω/sq) solar cells.

The crystallization characteristics of the glass frit can be regarded as an important factor. In a conventional glass frit, when performing a differential scanning calorimetry (DSC) measurement, the first crystallization occurs at a temperature of equal to or greater than 550° C. However, in the present invention, the first crystallization peak occurs at a temperature of less than 400° C. on DSC measurement data of the glass frit, whereby crystallization occurs more quickly during firing. This significantly reduces an increase in the line width of an electrode during firing, thereby making it possible to improve electrical characteristics. Preferably, on the DSC data, the first crystallization peak occurs at a temperature of less than 400° C., and the second crystallization peak occurs at a temperature of equal to or greater than 400° C. and equal to or less than 500° C. More preferably, all crystallization peaks occur at a temperature of 400° C. on the DSC data.

The organic vehicle including the organic binder and the solvent is required to have characteristics such as maintaining a uniform mixture of the metal powder, the glass frit, and the like. For example, when the conductive paste is applied to the substrate by screen printing, there is a need for characteristics that make the conductive paste homogeneous to suppress blurring and flow of a printed pattern, and also improve dischargeability and plate separation characteristics of the conductive paste from a screen plate.

Examples of the organic binder may include a cellulose ester compound such as cellulose acetate, cellulose acetate butyrate, and the like; a cellulose ether compound such as ethyl cellulose, methyl cellulose, hydroxy flopil cellulose, hydroxy ethyl cellulose, hydroxy propyl methyl cellulose, hydroxy ethyl methyl cellulose, and the like; an acrylic compound such as polyacrylamide, polymethacrylate, polymethyl methacrylate, polyethyl methacrylate, and the like; and a vinyl compound such as polyvinyl butyral, polyvinyl acetate, polyvinyl alcohol, and the like. At least one of the binders may be selected and used.

The solvent may be used by selecting at least one compound from the group consisting of dimethyl adipate, diethylene glycol butyl ether acetate, texanol, dioctyl phthalate, dibutyl phthalate, diethyleneglycol, ethylene glycol butyl ether, ethylene glycol butyl ether acetate, diethylene glycol butyl ether, and the like. Preferably, dimethyl adipate and diethylene glycol butyl ether acetate are used.

The conductive paste composition according to the present invention may further contain, as needed, other additives generally known, for example, dispersants, leveling agents, plasticizers, viscosity modifiers, surfactants, oxidizing agents, metal oxides, metal organic compounds, waxes, and the like.

The metal powder may be included in an amount of 40 to 98 parts by weight (e.g., 60 to 95 parts by weight) with respect to 100 parts by weight of the entire conductive paste in consideration of electrode thickness formed during printing and linear resistance of the electrode. When the amount of metal powder is less than 40 parts by weight (e.g., 60 parts by weight), specific resistance of a formed electrode may be high, and when the amount of metal powder is greater than 98 parts by weight (e.g., 95 parts by weight), there is a problem in that the metal powder may not be uniformly dispersed due to an insufficient amount of other components.

The glass frit may be included in an amount of 1 to 15 parts by weight with respect to 100 parts by weight of the entire conductive paste. When the amount of the glass frit is less than 1 part by weight, there is a possibility that electrical specific resistance may increase due to incomplete firing, and when the amount of the glass frit is greater than 15 parts by weight, there is a possibility that the electrical resistivity may increase due to too many glass components in a fired body of the silver powder. The organic binder may be included in an amount of 1 to 15 parts by weight with respect to 100 parts by weight of the entire conductive paste, but is not limited thereto. When the amount of the organic binder is less than 1 part by weight, viscosity of the composition and adhesive force of a folioed electrode pattern may decrease, and when the amount of the organic binder is greater than 15 parts by weight, the amount of metal powder, solvent, dispersant, and the like may not be sufficient.

The solvent may be included in an amount of 5 to 25 parts by weight with respect to 100 parts by weight of the entire conductive paste. When the amount of the solvent is less than 5 parts by weight, the metal powder, glass frit, organic binder, and the like may not be uniformly mixed, and when the amount of the solvent is greater than 25 parts by weight, the amount of the metal powder may be reduced and electrical conductivity of the produced front electrode 40 may be reduced thereby. The other additives may be included in an amount of 0.1 to 5 parts by weight with respect to 100 parts by weight of the entire conductive paste.

The above-described conductive paste for the solar cell electrode may be prepared by mixing and dispersing the metal powder, glass frit, organic binder, solvent, and additives, followed by filtering and degassing.

The present invention also provides a method of forming a solar cell electrode, characterized in that the conductive paste is coated on a substrate, dried, and fired, and provides a solar cell electrode produced by the method. In the method of forming the solar cell electrode according to the present invention, except that the conductive paste including the glass frit of the above characteristics is used, the substrate, printing, drying, and firing can be implemented by using methods generally used in manufacturing of solar cells.

In an example, the substrate may be a silicon wafer, and the electrode produced from the paste according to the present invention may be a finger electrode or a busbar electrode of the front electrode 40. The electrode may be printed on the passivation film 32 including the aluminum oxide film and then penetrate the passivation film 32 including the aluminum oxide film (more particularly, the passivation film 32 including the aluminum oxide film and the anti-reflection film 30) by fire-through during firing to be connected (e.g., electrically connected) to the first conductivity type region 20. The printing may be screen printing or offset printing, the drying may be performed at 90 to 250° C., and the firing may be performed at 600 to 950° C. Preferably, the firing is performed at 800 to 950° C., more preferably, high temperature/high speed firing is performed at 850 to 900° C. for 5 seconds to 1 minute, and the printing is performed to a thickness of 20 to 60μm. However, the present invention is not limited to this, and printing methods, drying and firing process conditions, and the like may be variously modified.

According to the present invention, the glass frit includes the alkali metal oxide in a specific molar ratio, and thus it is possible to effectively etch the aluminum oxide film and to improve the contact characteristics. Accordingly, it is possible to improve the fill factor and efficiency of the solar cell. Further, it is possible to effectively improve the contact characteristics by adjusting the amount of the composition (particularly the alkali metal oxide) in the glass frit in accordance with the thickness of the aluminum oxide film.

### Examples and Comparative Examples

A silver powder, a glass frit, an organic binder, a solvent, additives, and the like were added and dispersed using a 3-roll mill, and then a silver powder was mixed and dispersed using the 3-roll mill. Here, ethyl cellulose resin was used as the organic binder, and diethylene glycol butyl ether acetate was used as the solvent, and the silver powder had a spherical shape and had an average particle diameter of 1μm. The composition of a conductive paste during mixing is as shown in Table 1 below, the composition of a glass frit according to each of Examples 1 to 8 is as shown in Table 2, and the composition of a glass frit according to each of Comparative Examples 1 to 5 is as shown in Table 3. Thereafter, degassing under reduced pressure was performed to prepare a conductive paste.

TABLE 1

| | Examples and |
|---|---|
| Classification [wt. %] | comparative examples |
| Ethyl cellulose resin | 0.45 |
| Diethylene glycol butyl ether acetate | 6.3 |
| Wax | 0.28 |
| Silver powder | 88.5 |
| Glass frit | 3.1 |
| Dispersant (ED121) | 0.45 |
| Additive (polydimethylsiloxane oil) | 0.92 |

TABLE 2

| Classification | Example | Example | Example | Example | Example | Example | Example | Example |
|---|---|---|---|---|---|---|---|---|
| [mol %] | 1 | 2 | 3 | 4 | 5 | 6 | 7 | 8 |
| PbO | 25 | 29 | 25 | 25 | 25 | 17 | 25 | 25 |
| TeO₂ | 34 | 34 | 34 | 34 | 34 | 37 | 34 | 34 |
| Bi₂O₃ | 15 | 0 | 12 | 15 | 5 | 8 | 15 | 15 |
| SiO₂ | 5 | 10 | 5 | 5 | 7 | 15 | 5 | 5 |
| Li₂O | 7 | 5 | 5 | 10 | 8 | 9 | 6 | 13 |
| Na₂O | 5 | 5 | 5 | | 1 | 2 | 10 | 2 |
| K₂O | 5 | 5 | 10 | 7 | 6 | — | 1 | 2 |
| B₂O₃ | — | — | — | — | — | 2 | — | — |
| ZnO | 2 | 1 | 2 | 2 | 6 | 4 | 2 | 2 |
| Al₂O₃ | 2 | — | 2 | 2 | 5 | 1 | 2 | 2 |
| TiO₂ | — | 1 | — | — | 3 | 2 | — | — |
| CaO | — | — | — | — | — | 3 | — | — |
| ZrO₂ | — | — | 1 | — | — | — | — | — |
| Total | 100.0 | 100.0 | 100.0 | 100.0 | 100.0 | 100.0 | 100.0 | 100.0 |
| Total molar | 0.17 | 0.15 | 0.20 | 0.17 | 0.15 | 0.11 | 0.17 | 0.17 |
| ratio of alkali | | | | | | | | |
| metal oxide to | | | | | | | | |
| the entire glass | | | | | | | | |
| frit | | | | | | | | |

TABLE 3

| Classification | Comparative | Comparative | Comparative | Comparative | Comparative |
|---|---|---|---|---|---|
| [mol %] | example 1 | example 2 | example 3 | example 4 | example 5 |
| PbO | 30 | 27 | 27 | 25 | 20 |
| TeO₂ | 34 | 39 | 39 | 34 | 30 |
| Bi₂O₃ | 15 | 15 | 15 | 15 | 5 |
| SiO₂ | 9 | 7 | 7 | 8 | 5 |
| Li₂O | — | 5 | 3 | — | 10 |
| Na₂O | — | — | 1 | 4 | 10 |
| K₂O | — | — | 1 | 2 | 10 |
| B₂O₃ | — | — | — | — | — |
| ZnO | 10 | 2 | 2 | 7 | 10 |
| Al₂O₃ | 2 | 2 | 2 | 2 | — |
| TiO₂ | — | 2 | 3 | — | 3 |
| CaO | — | 1 | — | — | — |
| ZrO₂ | — | — | — | 3 | — |
| Total | 100.0 | 100.0 | 100.0 | 100.0 | 100.0 |
| Total molar ratio | 0.0 | 0.05 | 0.05 | 0.06 | 0.30 |
| of alkali metal | | | | | |
| oxide to the | | | | | |
| entire glass frit | | | | | |

### Test Examples

An n-type dopant was diffused on a front surface of a silicon wafer to form a first conductivity type region, and an anti-reflection film composed of a silicon nitride film and a passivation film composed of an aluminum oxide film were formed on the first conductivity type region. A conductive paste prepared according to each of the above Examples and Comparative Examples was pattern-printed on the silicon nitride film and the aluminum oxide film by screen printing using a 35μm mesh, and dried at 200 to 350° C. for 20 to 30 seconds using a belt-type drying furnace. Thereafter, an aluminum paste was printed on a back surface of the silicon wafer, and then dried in the same manner as above. Finally, firing was performed at a temperature of 500 to 900° C. for 20 to 30 seconds in a belt-type firing furnace, thereby producing a solar cell.

The produced solar cell was evaluated for etching characteristics of the aluminum oxide film from an electro luminescence image, and contact resistance was measured using a contact resistance meter. Here, when a front electrode formed by firing the conductive paste penetrates the aluminum oxide film and this is connected to the first conductivity type region, the etching characteristics of the aluminum oxide film were determined to be good, and when the front electrode cannot penetrate the aluminum oxide film and thus cannot be connected to the first conductivity type region, the etching characteristics of the aluminum oxide film were determined to be poor. Further, contact resistance is a contact resistance measured using a contact resistance meter when sheet resistance of a semiconductor substrate is 100 ohms and current density (Jsc) is 30 mA/cm². The results are shown in Table 4.

TABLE 4

| | Etching | Contact |
|---|---|---|
| | characteristics | resistance[ohm · cm²] |
| Example 1 | Good | 21.4 |
| Example 2 | Good | 24.7 |
| Example 3 | Good | 34.1 |
| Example 4 | Good | 23.5 |
| Example 5 | Good | 22.1 |
| Example 6 | Good | 37.3 |
| Example 7 | Good | 22.4 |
| Example 8 | Good | 20.9 |
| Comparative | Poor | — |
| example 1 | | |
| Comparative | Poor | — |
| example 2 | | |
| Comparative | Poor | — |
| example 3 | | |
| Comparative | Poor | — |
| example 4 | | |
| Comparative | Good | 67.3 |
| example 5 | | |

Referring to Table 4, it can be seen that in a solar cell according to each of Examples 1 to 8, the etching characteristics of an aluminum oxide film were good, and the contact resistance was very low at about equal to or less than 40 ohm·cm² (e.g., equal to or less than 25 ohm·cm², particularly 20.9 ohm·cm²), and thus the aluminum oxide film was etched effectively and stably. On the other hand, it can be seen that in a solar cell according to each of Comparative Examples 1 to 4, the etching characteristics of an aluminum oxide film was poor and thus measurement of the contact resistance could not be made, and thus a front electrode did not penetrate the aluminum oxide film. It can also be seen that in a solar cell according to Comparative Example 5, a front electrode penetrated an aluminum oxide film, but the contact resistance was very high at 67.3 ohm·cm². Accordingly, it can be seen that in the solar cell according to each of Comparative Examples 1 to 5, it was difficult for the front electrode to etch the aluminum oxide film effectively and stably.

As described above, it can be seen that, as in Examples 1 to 8, when the total molar ratio of an alkali metal oxide to the entire glass frit is 0.1 to 0.2, the aluminum oxide film was etched well and the contact resistance was low. On the other hand, it can be seen that, as in Comparative Examples 1 to 4, when the glass frit does not include an alkali metal oxide or the total molar ratio of the alkali metal oxide to the entire glass frit is less than 0, etching of the aluminum oxide film was not performed well. Further, it can be seen that, as in Comparative Example 5, when the total molar ratio of an alkali metal oxide to the entire glass frit is greater than 0.2, etching of the aluminum oxide film was made, but the contact resistance was high, which may not be suitable for improving the fill factor and efficiency of the solar cell.

Here, as in Examples 1, 4, 5, 7, and 8, when the glass frit includes all of lithium oxide, sodium oxide, and potassium oxide, and lithium oxide or sodium oxide is included in a higher molar ratio than potassium oxide, the contact characteristics can be further improved. In particular, as in Examples 1, 5, and 8, when lithium oxide is included in a higher molar ratio than each of sodium oxide and potassium oxide, the etching characteristics of the aluminum oxide film can be effectively improved. Accordingly, the glass frit may include the alkali metal oxide at a higher molar ratio than an alkaline earth metal oxide, and for example, the glass frit may not include the alkaline earth metal oxide.

The features, structures, and effects illustrated in individual exemplary embodiments as above can be combined or modified with other exemplary embodiments by those skilled in the art. Therefore, content related to such combinations or modifications should be understood to fall within the scope of the present invention.

### DESCRIPTION OF THE REFERENCE NUMERALS IN THE DRAWINGS

10: semiconductor substrate

20: first conductivity type region

30: anti-reflection film

32: passivation film

40: front electrode

50: second conductivity type region

60: second electrode

62: first electrode portion

64: second electrode portion

1. A glass frit contained in a conductive paste for a solar cell electrode, the glass frit comprising:
an alkali metal oxide,
wherein a total molar ratio of the alkali metal oxide to the entire glass frit is 0.1 to 0.2.

2. The glass frit of claim 1, wherein the alkali metal oxide comprises at least one of lithium oxide (Li₂O), sodium oxide (Na₂O), and potassium oxide (K₂O).

3. The glass frit of claim 2, wherein the alkali metal oxide is used by mixing at least two or more of the lithium oxide, the sodium oxide, and the potassium oxide.

4. The glass frit of claim 3, wherein
when the glass frit comprises the lithium oxide, a molar ratio of the lithium oxide to the entire glass frit is 0.01 to 0.13;
when the glass frit comprises the sodium oxide, a molar ratio of the sodium oxide to the entire glass frit is 0.01 to 0.1; and
when the glass frit comprises the potassium oxide, a molar ratio of the potassium oxide to the entire glass frit is 0.01 to 0.1.

5. The glass frit of claim 3, wherein the alkali metal oxide individually comprises the lithium oxide, the sodium oxide, and the potassium oxide, and the lithium oxide or the sodium oxide is comprised in a higher molar ratio than the potassium oxide.

6. The glass frit of claim 5, wherein the lithium oxide is comprised in a higher molar ratio than each of the sodium oxide and the potassium oxide.

7. The glass frit of claim 1, wherein the glass frit comprises lead oxide, tellurium oxide, bismuth oxide, and silicon oxide, and further comprises at least one of boron oxide, zinc oxide, aluminum oxide, titanium oxide, calcium oxide, magnesium oxide, and zirconium oxide.

8. The glass frit of claim 1, wherein the glass frit comprises the alkali metal oxide in a higher molar ratio than an alkaline earth metal oxide.

9. The glass frit of claim 1, wherein the glass frit does not comprise an alkaline earth metal oxide.

10. A conductive paste for a solar cell electrode, the conductive paste comprising:
a metal powder; a glass frit; an organic binder; and a glass frit,
wherein the glass frit is the glass frit according to claim 1.

11. A solar cell, comprising:
a semiconductor substrate;
a first conductivity type region formed on a front surface of the semiconductor substrate;
a passivation film formed on the first conductivity type region and including an aluminum oxide film;
a front electrode penetrating the passivation film to be connected to the first conductivity type region; and
a back electrode formed on a back surface of the semiconductor substrate,
wherein the front electrode is produced by applying the conductive paste of claim 10, followed by firing.

12. The solar cell of claim 11, wherein the front electrode has a contact resistance of equal to or less than 40 ohm·cm².
